(19) United States
(12) Patent Application Publication
(10) Pub. No.: US 2022/0399698 A1
(43) Pub. Date: Dec. 15, 2022

(54) REGULATOR CIRCUIT AND REGULATOR SYSTEM FOR TUNABLE LASER

(71) Applicant: Han's OE&C Technologies Co., Ltd., Shenzhen (CN)

(72) Inventors: Zhiyong LI, Shenzhen (CN); Jiaxiong WANG, Shenzhen (CN); Zhinong LOU, Shenzhen (CN); Yunfeng GAO, Shenzhen (CN)

(21) Appl. No.: 17/572,253

(22) Filed: Jan. 10, 2022

(30) Foreign Application Priority Data
Jun. 10, 2021 (CN) 202110646600.5

(51) Int. Cl. H01S 5/024; H01S 5/06; H01S 5/0683

(52) U.S. Cl. CPC H01S 5/02415; H01S 5/0612; H01S 5/06837

(57) ABSTRACT

The present disclosure discloses a regulator circuit and regulator system for a tunable laser, the regulator circuit for the tunable laser includes a control module, a digital-to-analog conversion module and a semiconductor temperature regulation module; after the regulator circuit for the tunable laser is powered on, the control module is configured to send a control signal to the digital-to-analog conversion module, the digital-to-analog conversion module is configured to convert the control signal into an analog voltage signal and send the analog voltage signal to the semiconductor temperature regulation module, the semiconductor temperature regulation module is configured to cool or heat the tunable laser according to the received analog voltage signal.

### CROSS REFERENCE TO RELATED APPLICATION

The present application claims priority to Chinese Patent Application No. 202110646600.5, filed on Jun. 10, 2021 and entitled “Regulator Circuit and Regulator System for Tunable Laser”, and the content of which is herein incorporated by reference in its entirety.

### TECHNICAL FIELD

The present disclosure relates to a field of tunable laser technology, and particularly to a regulator circuit and regulator system for a tunable laser.

### BACKGROUND

An Integrated Tunable Laser Assembly (ITLA) refers to a laser which can continuously change the output wavelength of the laser within a certain range. Such laser has a wide range of uses, and can be used in spectroscopy, photochemistry, medicine, biology, integrated optics, pollution monitoring, semiconductor material processing, information processing, and communications, etc. The research on the tunable lasers has been a hot topic in recent years.

The tunable laser is very sensitive to the temperature. The power and frequency of the tunable laser can be regulated by regulating the temperature. In the prior art, the temperature of the filter on the optical path of the tunable laser is generally controlled by a control chip combined with a heater, and then the frequency and the power of the tunable laser are regulated. However, such regulation mode has disadvantages of low control accuracy and slow regulation speed in the temperature, etc.

### SUMMARY

In view of the above-mentioned shortcomings of the prior art, the present disclosure provides a regulator circuit and regulator system for a tunable laser, which can regulate the frequency and power of the tunable laser fast and accurately.

The present embodiment adopts the following technical solution:

A regulator circuit for a tunable laser, including a control module, a digital-to-analog conversion module and a semiconductor temperature regulation module, wherein after the regulator circuit for the tunable laser is powered on, the control module is configured to send a control signal to the digital-to-analog conversion module, the digital-to-analog conversion module is configured to convert the control signal into an analog voltage signal and send the analog voltage signal to the semiconductor temperature regulation module, the semiconductor temperature regulation module is configured to cool or heat the tunable laser according to the received analog voltage signal.

Further, in the regulator circuit for the tunable laser, the control module includes a control chip connected to the digital-to-analog conversion module.

Further, in the regulator circuit for the tunable laser, the control chip is configured to transmit a signal to the digital-to-analog conversion module through an SPI protocol.

Further, in the regulator circuit for the tunable laser, the digital-to-analog conversion module includes a DAC chip connected to the control module and the semiconductor temperature regulation module, respectively.

Further, in the regulator circuit for the tunable laser, the semiconductor temperature regulation module includes a TEC and a TEC driver chip which is connected to the digital-to-analog conversion module and the TEC, respectively.

Further, in the regulator circuit for the tunable laser, the semiconductor temperature regulation module further includes a temperature sensor connected to the TEC driver chip and configured to detect a temperature of the TEC.

Further, in the regulator circuit for the tunable laser, further including a feedback module which is connected to the semiconductor temperature regulation module and the control module respectively and is configured to feed back a drive current and a control temperature of the semiconductor temperature regulation module to the control module.

Further, in the regulator circuit for the tunable laser, the feedback module includes an ADC chip connected to the semiconductor temperature regulation module and the control module, respectively.

Further, in the regulator circuit for the tunable laser, the ADC chip is configured to transmit a signal to the control module through an SPI protocol.

A regulator system for a tunable laser, including a tunable laser and any one of the regulator circuit for the tunable laser above-mentioned, the tunable laser is sequentially provided with a first frequency modulation filter, a phase modulation filter and a second frequency modulation filter on an optical path; the semiconductor temperature regulation module includes three groups of semiconductor temperature regulation sub-modules, the three groups of semiconductor temperature regulation sub-modules are connected to the digital-to-analog conversion module and configured to regulate temperatures of the first frequency modulation filter, the phase modulation filter and the second frequency modulation filter, respectively.

Compared with the prior art, the regulator circuit and the regulator system for the tunable laser provided by the present disclosure can convert the control signal sent by the control module into a high-precision voltage signal through the digital-to-analog conversion module, and makes the semiconductor temperature regulation module cool or heat the tunable laser accurately, so that the frequency and power of the tunable laser can be regulated fast and accurately.

### BRIEF DESCRIPTION OF THE DRAWINGS

FIG. 1 is a principle block diagram of a regulator circuit for a tunable laser according to the present disclosure.

FIG. 2 is a schematic structure diagram of a control module in the regulator circuit for the tunable laser shown in FIG. 1 according to an embodiment of the present disclosure.

FIG. 3 is a schematic structure diagram of a digital-to-analog conversion module in the regulator circuit for the tunable laser shown in FIG. 1 according to an embodiment of the present disclosure.

FIG. 4 is a schematic structure diagram of a semiconductor temperature regulation module in the regulator circuit for the tunable laser shown in FIG. 1 according to an embodiment of the present disclosure.

FIG. 5 is a schematic structure diagram of a feedback module in the regulator circuit for the tunable laser shown in FIG. 1 according to an embodiment of the present disclosure.

### DETAILED DESCRIPTION

In order to make the purpose, technical solution and advantages of the present disclosure clearer, the present disclosure will be described in further detail below with reference to the accompanying drawings and embodiments. It should be understood that the specific embodiments described herein are only used for explaining the present disclosure, rather than limiting the present disclosure. Without further description, elements, structures, and features in an embodiment can also be beneficially combined with other embodiments.

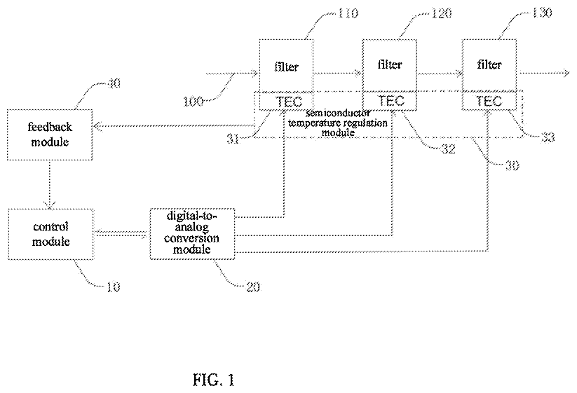

Referring to FIG. 1, a regulator circuit for a tunable laser provided by the present disclosure includes a control module 10, a digital-to-analog conversion module 20 and a semiconductor temperature regulation module 30. After the regulator circuit for the tunable laser is powered on, the control module 10 sends a control signal to the digital-to-analog conversion module 20; and the digital-to-analog conversion module 20 converts the control signal into an analog voltage signal and sends the analog voltage signal to the semiconductor temperature regulation module 30; the semiconductor temperature regulation module 30 cools or heats the tunable laser according to the received analog voltage signal.

The control module 10 is connected to an input end of the digital-to-analog conversion module 20 through a Serial Peripheral Interface (SPI) bus. The SPI bus is a four-wire bus which can realize high-speed and high-efficiency communication between the control module 10 and the digital-to-analog conversion module 20. An output end of the digital-to-analog conversion module 20 is connected to a control end of the semiconductor temperature regulation module 30. The semiconductor temperature regulation module 30 can be provided in the tunable laser to heat or cool each group of filters through a semiconductor device.

When the regulator circuit for the tunable laser operates, the control module 10 is configured to send a corresponding signal to the digital-to-analog conversion module 20 according to regulation requirements of the frequency and power of the tunable laser. The control signal is generally a digital voltage signal; and the digital-to-analog conversion module 20 can convert the digital voltage signal sent by the control module 10 into an analogy voltage signal, and improve the accuracy of the voltage signal. The semiconductor temperature regulation module 30 receives a high-precision voltage signal and can cool or heat each group of filters in the tunable laser accurately based on the high-precision voltage signal, thereby implementing the regulation requirements of the frequency and power of the tunable laser.

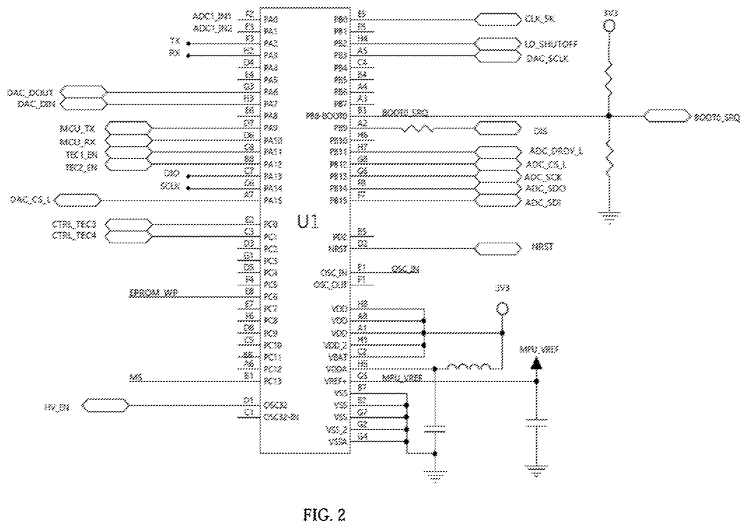

Referring to FIG. 2, a structure diagram of a control module 10 is provided according to an embodiment of the present disclosure. The control module 10 includes a control chip U1, and controls the semiconductor temperature regulation module 30 to heat or cool through the control chip U1. An SPI function block pin of the control chip U1 is connected to the digital-to-analog conversion module 20, and outputs a voltage corresponding to a temperature value needing to be controlled to the digital-to-analog conversion module 20 through the SPI protocol.

A model of the control chip U1 can be selected as STM32G431RBI, which is a 170 MHz mainstream MCU chip with DSP and FPU and can better implement the temperature regulation function. Other control chips of different models but capable of achieving the same function can also be selected in other embodiments naturally, which is not limited in the present disclosure.

The control module 10 further includes a peripheral circuit of the control chip U1, such as a filter circuit, a reset circuit, and a crystal oscillator circuit, etc. The specific circuit structure of the peripheral circuit can be designed according to the chip design manual and the relevant general circuit structure in this field, which is not described in detail in the present disclosure.

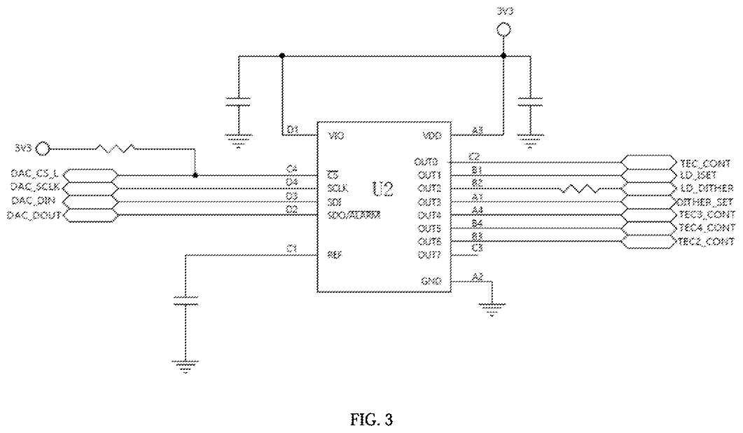

Referring to FIG. 3, a structure diagram of a digital-to-analog conversion module 20 is provided according to an embodiment of the present disclosure. The digital-to-analog conversion module 20 includes a Digital to Analog Convertor (DAC) chip. An SPI function block pin of the DAC chip U2 is connected to the SPI function block pin of the control chip U1; and an output pin of the DAC chip U2 is connected to the control end of the semiconductor temperature regulation module 30. After the DAC chip U2 receives the voltage corresponding to the temperature value needing to be controlled from the control chip U1, the voltage can be converted into a high-precision analog voltage signal and transmitted to the semiconductor temperature regulation module 30 through the output pin.

The model of the DAC chip U2 can be selected as DAC80508MYZFT, which has a precise internal reference voltage and can output a high-precision regulation voltage. The DAC chips of other models but capable of achieving the same function can also be used in other embodiments naturally, which is not limited in the present disclosure. At the same time, the digital-to-analog conversion module 20 further includes a peripheral circuit of the DAC chip U2. Similar to the peripheral circuit of the control chip U1, the specific structure of the peripheral circuit for the DAC chip U2 is not described in detail in the present disclosure.

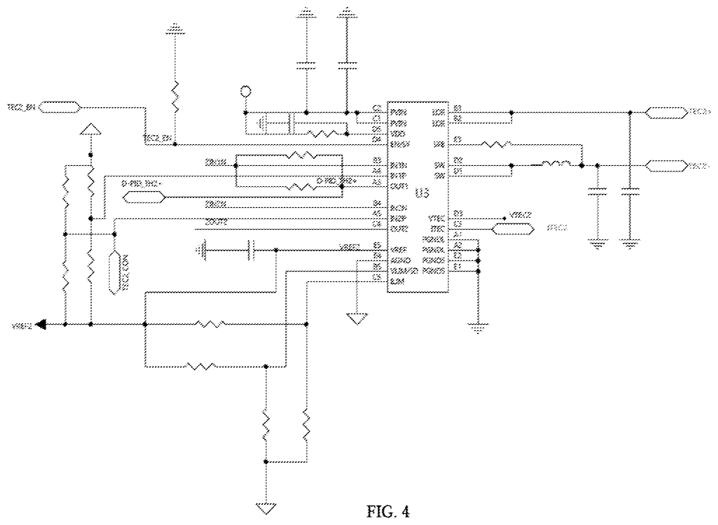

Referring to FIG. 4, a structure diagram of a semiconductor temperature regulation module 30 is provided according to an embodiment of the present disclosure. The semiconductor temperature regulation module 30 includes a Thermo Electric Cooler (TEC) and a TEC driver chip U3. The TEC is a thermoelectric cooling component made by using the Peltier effect of the semiconductor material, which has advantages of light weight, small size, and high cooling capacity. In addition, when the polarity of the operating current of the TEC is changed, heating can also be performed. The TEC driver chip U3 is configured to output a driving voltage to the TEC, so that the TEC performs cooling or heating under the driving voltage.

At the same time, the semiconductor temperature regulation module 30 further includes a peripheral circuit of the TEC driver chip U3, and a parameter corresponding to a chip specification is set in the peripheral circuit, so that the TEC driver chip U3 can output a driving voltage of the TEC according to the parameter of the peripheral circuit through an internal system when receiving the analog voltage signal sent by the DAC chip U2. According to the driving voltage received, the TEC heats or cools accurately with the required temperature regulation value as a target to achieve the rapid and high-precision temperature regulation of the tunable laser.

The model of the TEC-driving chip U3 can be selected as ADN8834ACBZ-R7. The chips of other models but capable of achieving the same function can also be used in other embodiments naturally, which is not limited in the present disclosure. At the same time, for the structure of the peripheral circuit and the setting parameters of the TEC driver chip U3, reference can be made to the chip design manual, the specific structure of the peripheral circuit of the TEC driver chip U3 is not be described in detail in the present disclosure.

Further, the regulator circuit for the tunable laser can further includes a feedback module 40, which is connected to the semiconductor temperature regulation module 30 and the control module 10, respectively. The feedback module 40 is configured to feed back a current and a temperature of the semiconductor temperature regulation module 30 to the control module 10 to determine, by the control module 10, whether the current and the temperature of the semiconductor temperature regulation module 30 meet the requirement, thereby completing a closed-loop regulation process.

At the same time, in order to implement the temperature detection on the TEC driver chip U3, a temperature sensor can be provided on the periphery of the TEC. The temperature of the TEC is detected by the temperature sensor, and the temperature detected is transmitted back to the TEC driver chip U3. Specifically, the temperature sensor can be implemented by a thermistor, a temperature sensor chip, etc., and an output end thereof is connected to relevant pins of the TEC driver chip U3.

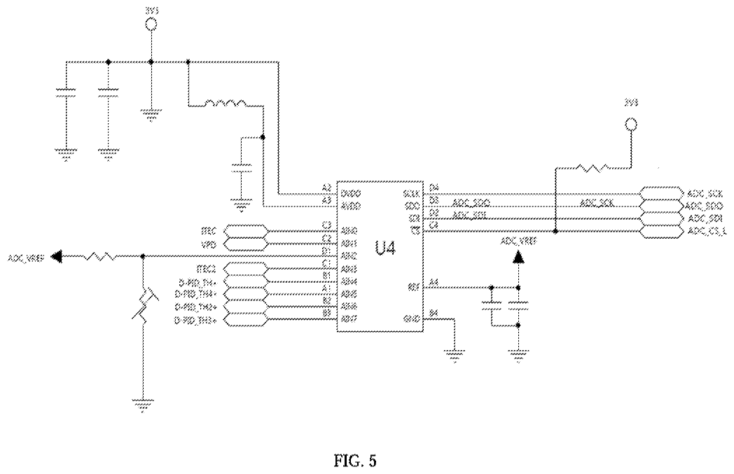

Referring to FIG. 5, a structure diagram of a feedback module 40 is provided according to an embodiment of the present disclosure. The feedback module 40 includes an Analog to Digital Convertor (ADC) chip U4, which is connected to the semiconductor temperature regulation module 30 and the control module 10, respectively.

In a specific embodiment, the ADC chip U4 is connected to a relevant signal output pin of the TEC driver chip U3 through a signal input pin, so that the TEC driver chip U3 can send a temperature signal and a current signal during or after an operation to the ADC chip U4; the ADC chip U4 converts the temperature signal and the current signal into analog signals, and then transmits the analog signals to the control chip U1 through the SPI bus, such that the control chip U1 determines whether the temperature and the current of the TEC driver chip U3 meet the settings, to complete the closed-loop regulation process of the regulator circuit for the tunable laser.

In order to better understand the present disclosure, please refer to FIG. 1 to FIG. 5, a regulation process of a regulator circuit for a tunable laser is described in detail in conjunction with specific embodiments below.

The control chip U1 is connected to relevant pins (corresponding to pins D2/D3/D4/C4) of the DAC chip U2 through SPI function pins (corresponding to pins D2/D3/D4/C4). First, the control chip U1 outputs a voltage corresponding to a temperature value needing to be controlled and transmits the voltage to the DAC chip U2 through the SPI protocol.

Then, after converting a voltage signal sent by the control chip U1 into a high-precision voltage signal, the DAC chip U2 outputs the high-precision voltage signal to a pin C4 of the TEC driver chip U3 through a pin B3.

The TEC driver chip U3 outputs a corresponding TEC driving voltage according to the received high-precision voltage signal to drive the TEC to cool or heat each group of filters in the tunable laser. At the same time, a temperature sensor sends a temperature detected itself during or after a TEC controlling process to the TEC driver chip U3 through a pin TH2+ of the TEC driver chip U3.

Secondly, a current during or after the control process of the TEC driver chip U3 is transmitted to a pin C2 of the ADC chip U4 through the pin C3. A temperature during or after the TEC control process is transmitted to a pin B2 of the ADC chip U4 through a pin A3 of the TEC control chip U1.

After converting the current signal and the temperature signal received into digital signals, the ADC chip U4 sends the digital signals to the control chip U1 (corresponding to pins F7/F8/G6/G8) through the SPI protocol (corresponding to pins D2/D3/D4/C4) to determine whether the temperature and the current meet the setting requirements.

The control chip U1 and the DAC chip U2 are responsible for providing the high-precision voltage control value; and the TEC driver chip U3 and the TEC are responsible for providing the high-precision temperature control for the filters in the tunable laser; and the temperature sensor is responsible for detecting the temperatures of the filters; and the ADC chip U4 is responsible for feeding back a detection result to the control chip U1 to achieve a closed-loop regulation process.

In addition, please continue to refer to FIG. 1, the present disclosure also provides a regulator system for a tunable laser, including a tunable laser and the above-mentioned regulation circuit for the tunable laser. The tunable laser is sequentially provided with a first frequency modulation filter 110, a phase modulation filter 120 and a second frequency modulation filter 130 on an optical path 100. The semiconductor temperature regulation module includes three groups of semiconductor temperature regulation sub-modules connected to the digital-to-analog conversion module 20, that is, a first semiconductor temperature regulation sub-module 31 configured to regulate the temperature of the first frequency modulation filter 110, a second semiconductor temperature regulation sub-module 32 configured to regulate the temperature of the phase modulation filter 120, and a third semiconductor temperature regulation sub-module 33 configured to regulate the temperature of the second frequency modulation filter 130; and the three groups of semiconductor temperature regulation sub-modules each include a corresponding TEC and a TEC driver chip.

The control module 10 in the regulator circuit for the tunable laser can heat or cool the first frequency modulation filter 110 by controlling the first semiconductor temperature regulation sub-module 31 and heat or cool the second frequency modulation filter 130 by controlling the third semiconductor temperature regulation sub-module 33, to regulate the frequency of the tunable laser. At the same time, the control module 10 can also heat or cool the phase modulation filter 120 through the second semiconductor temperature regulation sub-module 32 to regulate the laser phase, thereby implementing the power regulation of the tunable laser.

In conclusion, the regulator circuit and the regulator system for the tunable laser in the present disclosure have the following advantages:

1. The temperature control precision is high.

2. The software control is simple and has low difficulty.

3. Speed of the temperature regulation speed is fast, so that the tunable laser can take less time to reach the required regulation frequency and power.

It can be understood that for those of ordinary skill in the art, equivalent substitutions or transformations can be made according to the technical solution and inventive concept of the present disclosure, and all these transformations or substitutions should within the protection scope of the appended claims of the present disclosure.

1. A regulator circuit for a tunable laser, comprising a control module, a digital-to-analog conversion module and a semiconductor temperature regulation module, wherein after the regulator circuit for the tunable laser is powered on, the control module is configured to send a control signal to the digital-to-analog conversion module, the digital-to-analog conversion module is configured to convert the control signal into an analog voltage signal and send the analog voltage signal to the semiconductor temperature regulation module, the semiconductor temperature regulation module is configured to cool or heat the tunable laser according to the received analog voltage signal.

2. The regulator circuit for the tunable laser according to claim 1, wherein the control module comprises a control chip connected to the digital-to-analog conversion module.

3. The regulator circuit for the tunable laser according to claim 2, wherein the control chip is configured to transmit a signal to the digital-to-analog conversion module through an SPI protocol.

4. The regulator circuit for the tunable laser according to claim 1, wherein the digital-to-analog conversion module comprises a DAC chip connected to the control module and the semiconductor temperature regulation module, respectively.

5. The regulator circuit for the tunable laser according to claim 1, wherein the semiconductor temperature regulation module comprises a TEC and a TEC driver chip which is connected to the digital-to-analog conversion module and the TEC, respectively.

6. The regulator circuit for the tunable laser according to claim 5, wherein the semiconductor temperature regulation module further comprises a temperature sensor connected to the TEC driver chip and configured to detect a temperature of the TEC.

7. The regulator circuit for the tunable laser according to claim 1, further comprising a feedback module which is connected to the semiconductor temperature regulation module and the control module respectively and is configured to feed back a drive current and a control temperature of the semiconductor temperature regulation module to the control module.

8. The regulator circuit for the tunable laser according to claim 7, wherein the feedback module comprises an ADC chip connected to the semiconductor temperature regulation module and the control module, respectively.

9. The regulator circuit for the tunable laser according to claim 8, wherein the ADC chip is configured to transmit a signal to the control module through an SPI protocol.

10. A regulator system for a tunable laser, comprising the tunable laser and the regulator circuit for the tunable laser according to claim 1, wherein the tunable laser is sequentially provided with a first frequency modulation filter, a phase modulation filter and a second frequency modulation filter on an optical path, the semiconductor temperature regulation module comprises three groups of semiconductor temperature regulation sub-modules, the three groups of semiconductor temperature regulation sub-modules are connected to the digital-to-analog conversion module and configured to regulate temperatures of the first frequency modulation filter, the phase modulation filter and the second frequency modulation filter, respectively.
